(19) United States
(12) Patent Application Publication
(10) Pub. No.: US 2014/0167012 A1
(43) Pub. Date: Jun. 19, 2014

(54) ORGANIC LIGHT-EMITTING DIODE DEVICE, METHOD FOR PACKAGING THE SAME AND DISPLAY DEVICE

(71) Applicant: BOE Technology Group Co., Ltd., Beijing (CN)

(72) Inventors: Zhongyuan Sun, Beijing (CN); Zengsheng He, Beijing (CN)

(73) Assignee: BOE Technology Group Co., Ltd., Beijing (CN)

(21) Appl. No.: 14/105,833

(22) Filed: Dec. 13, 2013

(30) Foreign Application Priority Data
Dec. 17, 2012 (CN) 201210548514.1

(51) Int. Cl. H01L 51/52; H01L 51/56

(52) U.S. Cl. CPC H01L 51/5259; H01L 51/56
USPC 257/40; 438/28

(57) ABSTRACT

The present invention provided an OLED device, a method for packaging the same, and a display device. With the solution of the present invention, it is not necessary to dispose a recess in the package substrate and the cost of production and thickness of the package substrate are decreased. The OLED device comprises a package substrate and an array substrate a surface of which is formed thereon with an OLED structure. Edges of the array substrate and the package substrate are bonded by a frame sealant, and the OLED structure is positioned between the array substrate and the package substrate. The OLED device further comprises a moisture barrier layer on a surface of the OLED structure for block moisture and oxygen and a desiccant layer positioned between the moisture layer and the package substrate, the desiccant layer including desiccant particles for absorbing moisture and oxygen within the OLED device.

### CROSS-REFERENCE TO RELATED APPLICATION

This application claims the benefit of Chinese Patent Application No. 201210548514.1 filed on Dec. 17, 2012 in the State Intellectual Property Office of China, the whole disclosure of which is incorporated herein by reference.

### BACKGROUND OF THE INVENTION

1. Field of the Invention

The present invention relates to a display technical field, more particular, relates to an OLED (Organic Light-Emitting Diode) device, a method for packaging the same, and a display device.

2. Description of the Related Art

An OLED device has become a very competitive and promising next-generation display technology due to the following advantages: a full solid-state structure, a high brightness, a wide view angle, a fast response speed, a wide operating temperature range, realization of flexible display or the like. An organic light emitting material and a cathode material used in the OLED device are particularly sensitive to water and oxygen and thus the life of the OLED device will be adversely affected by high humidity or oxygen content. In order to achieve a design life of 10,000 h, water permeability and oxygen permeability are often required to be less than 5×10⁶g/m²·day and 10⁻³ m³/m²·day respectively, which puts higher requirements on package of the OLED device.

Conventionally, in order to effectively block water and oxygen from entering the OLED device, for example, the OLED device is often packaged by using a back-cover type packaging. The structure of the conventional OLED device using the back-cover type packaging is shown in FIG. 1, wherein a surface of a package substrate 11 is affixed with a desiccant sheet 12. In order to eliminate a step on the surface of the package substrate 11, the package substrate 11 is provided with a recess into which the desiccant sheet 12 is affixed and a depth of which is larger than a thickness of the desiccant sheet 12. A TFT (Thin Film Transistor) array substrate used as a lower substrate 13 is vapor deposited thereon with an OLED structure 14. The package substrate 11 and the TFT array substrate 14 are bonded to each other by using a frame sealant 15 to obtain a device structure which is sealed to block the water and oxygen in air from entering. A main component of the desiccant sheet 12 may comprise calcium oxide, strontium oxide or the like for absorbing the moisture and oxygen in a closed space of the OLED device to extend the life of the OLED device.

In the existing OLED packaging method, the recess on the package substrate has to be formed by a method such as etching, which increases cost of production; further, the required depth of the recess in the package substrate results in a sharp increasing of the total thickness of the package substrate, which makes difficult to achieve a light and thin product.

### SUMMARY OF THE INVENTION

Embodiments of the present invention provide an OLED device, a method for packaging the same and a display device, wherein no recess is provided in a package substrate, thus the cost for producing is decreased and the thickness of the packaging substrate is reduced.

According to an aspect of the present invention, there is provided an OLED device comprising a package substrate, and an array substrate a surface of which is formed thereon with an OLED structure, wherein edges of the array substrate and the package substrate are bonded by a frame sealant, and the OLED structure is positioned between the array substrate and the package substrate. The OLED device further comprises a desiccant layer disposed between the OLED structure and the package substrate, the desiccant layer including desiccant particles for absorbing moisture and oxygen within the OLED device.

Alternatively, the desiccant layer is disposed on a surface of the package substrate facing the array substrate.

Alternatively, a surface of the OLED structure is provided thereon with a moisture barrier layer for blocking moisture and oxygen, and the desiccant layer is positioned between the moisture barrier layer and the package substrate. Further, the desiccant layer may be disposed on the moisture barrier layer, or the desiccant layer may be disposed on a surface of the package substrate facing the array substrate.

Alternatively, the desiccant particles include at least one of calcium oxide and strontium oxide.

Alternatively, the desiccant particles may be spherical desiccant, a diameter of the spherical desiccant being in the range of 0.04 mm to 0.07 mm.

The OLED device may further comprise a spacer provided between the array substrate and the package substrate for ensuring a thickness of the space between the array substrate and the package substrate.

The spacer may be positioned within the frame sealant.

The spacer may comprise a spherical spacer of silicon, and a diameter of the spherical spacer of silicon is larger than a total thickness of all layers between the array substrate and the package substrate.

Alternatively, the moisture barrier layer comprises a thin film of silicon nitride or silicon oxide, and a thickness of the moisture barrier layer is in the range of 2000 Å to 20000 Å.

According to another aspect of the present invention, there is provided a display device comprising the OLED device described above.

According to a further aspect of the present invention, there is provided a method for packaging an OLED device, the method comprising: providing a package substrate and an array substrate; forming an OLED structure on a surface of the array substrate; forming a desiccant layer between the OLED structure and a surface of the package substrate facing the array substrate, the desiccant layer including desiccant particles for absorbing moisture and oxygen within the OLED device; and bonding edges of the array substrate and the package substrate by a frame sealant.

Alternatively, the desiccant layer is formed on the surface of the package substrate facing the array substrate. The desiccant layer is formed by spraying, through a dry dispersion process, the desiccant particles for absorbing the moisture and oxygen within the OLED device onto the surface of the package substrate facing the array substrate, wherein the dry dispersion process is performed in a pure nitrogen atmosphere and concentration values of the water and oxygen are less than or equal to 10 ppm.

Alternatively, the method further comprises forming a moisture bather layer on the surface of the array substrate on which the OLED is formed, wherein the step of forming a desiccant layer comprises forming the desiccant layer on the moisture barrier layer. Further, the step of forming the desiccant layer on the moisture bather layer comprises forming the desiccant layer by spraying, through a dry dispersion process, the desiccant particles for absorbing the moisture and oxygen within the OLED device onto the moisture barrier layer, wherein the dry dispersion process is performed in a pure nitrogen atmosphere and concentration values of the water and oxygen are less than or equal to 10 ppm.

The step of forming an OLED structure on a surface of the array substrate comprises forming the OLED structure on the surface of the array substrate by a vapor deposition process.

Alternatively, the desiccant particles are spherical desiccant, a diameter of the spherical desiccant being in the range of 0.04 mm to 0.07 mm.

Alternatively, the method for packaging an OLED device further comprises providing a spacer between the array substrate and the package substrate for ensuring a thickness of the space between the array substrate and the package substrate. Alternatively, the spacer is positioned within the frame sealant.

The spacer may comprise a spherical spacer of silicon, and a diameter of the spherical spacer of silicon is larger than a total thickness of all layers between the array substrate and the package substrate.

Alternatively, the moisture barrier layer comprises a thin film of silicon nitride or silicon oxide; and a thickness of the moisture barrier layer is in the range of 2000 Å to 20000 Å.

Alternatively, the desiccant particles include at least one of calcium oxide and strontium oxide.

Embodiments of the present invention provide an OLED device, a method for packaging the same, and a display device. The OLED device comprises a package substrate, and an array substrate a surface of which is formed thereon with an OLED structure, wherein edges of the array substrate and the package substrate are bonded by a frame sealant, and the OLED structure is positioned between the array substrate and the package substrate, a desiccant layer is disposed between the OLED structure and the package substrate, and the desiccant layer includes desiccant particles for absorbing moisture and oxygen within the OLED device.

In the OLED device with such a structure, the packaging method and the display device according to the present invention, the same drying effect as that of the desiccant sheet may be obtained by the desiccant particles (for example, dispersed uniformly on the surface of the OLED structure), thus, the desiccant particles may replace the desiccant sheet in prior art, such that it is not necessary to dispose in the package substrate a recess for bonding the desiccant sheet, thus the cost of production and the thickness of the package substrate are decreased.

### BRIEF DESCRIPTION OF THE DRAWINGS

The above and other features of the present invention will become more apparent by describing in detail exemplary embodiments thereof with reference to the accompanying drawings, in which:

FIG. 1 is a schematic structural view showing an OLED device in the prior art;

FIG. 2 is a schematic structural view showing an OLED device according to an embodiment of the present invention; and

FIG. 3 is a flow chart showing a method for packaging an OLED device according to an embodiment of the present invention.

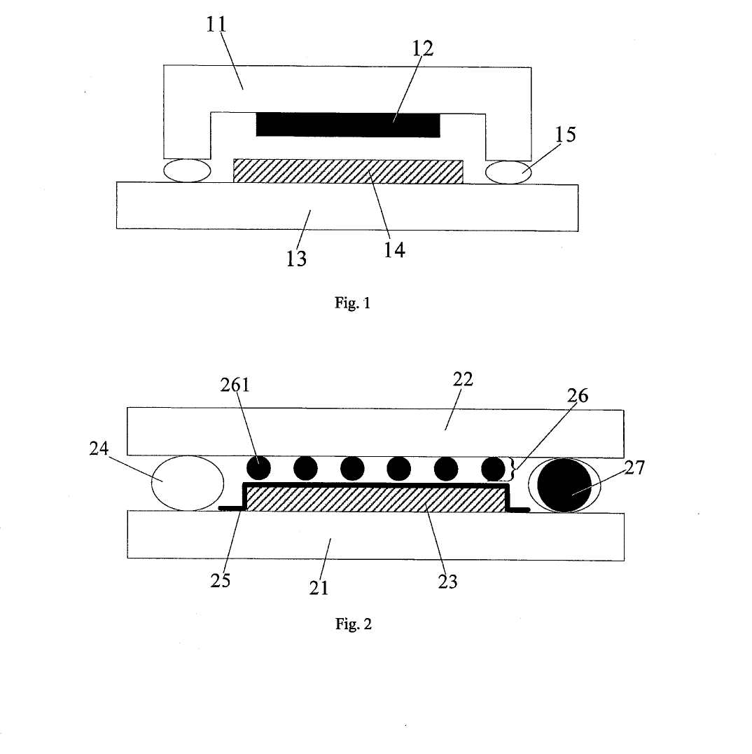

### LIST OF REFERENCE NUMERALS

11. package substrate

12. desiccant sheet

13. TFT array substrate

14. OLED structure

15. frame sealant

21. array substrate

22. package substrate

23. OLED structure

24. frame sealant

25. moisture barrier layer

26. desiccant layer

261. desiccant particles

27. spacer.

### DETAILED DESCRIPTION OF PREFERRED EMBODIMENTS OF THE INVENTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

As shown in FIG. 2, an OLED device according to an exemplary embodiment of the present invention comprises a package substrate 22, and an array substrate 21 a surface of which is formed thereon with an OLED structure 23, wherein edges of the array substrate 21 and the package substrate 22 are bonded by a frame sealant 24, and the OLED structure 23 is positioned between the array substrate 21 and the package substrate 22.

Alternatively, a surface of the OLED structure 23 is formed thereon with a moisture barrier layer 25 for blocking moisture and oxygen.

The OLED device further comprises a desiccant layer 26 disposed between the moisture barrier layer 25 and the package substrate 22. The desiccant layer 26 includes desiccant particles 261 for absorbing the moisture and oxygen within the OLED device. The desiccant layer 26 may be provided onto the moisture barrier layer 25.

It is noted that it is unnecessary to provide the moisture barrier layer 25. In this case, the desiccant layer 26 may be disposed on a surface of the package substrate 22 facing the array substrate 21.

The OLED device according to the embodiments of the present invention comprises a package substrate, and an array substrate a surface of which is formed thereon with an OLED structure, wherein edges of the array substrate and the package substrate are bonded by a frame sealant, and the OLED structure is positioned between the array substrate and the package substrate, a desiccant layer is disposed between the OLED structure and the package substrate, and the desiccant layer includes desiccant particles for absorbing moisture and oxygen within the OLED device. In the OLED device with such a structure, the same drying effect as that of the desiccant sheet may be obtained by the desiccant particles (for example, dispersed uniformly on the surface of the OLED structure), thus, the desiccant particles may replace the desiccant sheet in prior art, such that it is not necessary to dispose in the package substrate a recess for bonding the desiccant sheet, thus the cost of production and the thickness of the package substrate are decreased.

It is noted that the desiccant layer 26 may include desiccant particles 261 of various shapes, and it is not intended to limit the present invention. For example, in the OLED device as shown in FIG. 2, the desiccant particles 261 may comprise spherical desiccant, a diameter d of which may be in the range of 0.04 mm to 0.07 mm. The spherical desiccant may be dispersed uniformly on the desiccant layer when a dry dispersing process is used. Further, the spherical desiccant has a large surface area, which may further facilitate absorbing the moisture and oxygen within the OLED device to meet requirements of the OLED device regarding water permeability and oxygen permeability.

In addition, the spherical desiccant having such a dimension may be dispersed directly on the surface of the OLED structure by the existing dry dispersing process, wherein an existing apparatus for dispersing a spherical spacer may be used as a dry dispersing apparatus, and the used gas is pure nitrogen and concentration values of the water and oxygen in a dispersing room are less than or equal to 10 ppm during the dry dispersing process.

Specifically, taking the production of a typical desiccant layer of 0.12 mm thickness as an example, the total volume of the desiccant layer is defined by V=10 mm×10 mm×0.12 mm=12 mm³. The volume of a spherical desiccant of 0.04 mm diameter is defined by V_{0.04}=4/3·π·R³=4/3×3. 14×(0.02 mm)³=3. 35×10⁻⁵ mm³. The volume of a spherical desiccant of 0.07 mm diameter is defined by V_{0.07}=4/3·π·R³=4/3×3. 14×(0.07 mm)³=1.79×10⁻⁴ mm³. In an exemplary embodiment, densities of the two types of spherical desiccant having the above dimensions are calculated taking 2.4 inch display device as an example, specifically, the density of spherical desiccant of 0.04 mm diameter is defined by σ_{0.04}=V+V_{0.04}+S(Panel Size)=181.2 ea/mm², and the density of spherical desiccant of 0.07 mm diameter is defined by σ_{0.007}=V+V_{0.07}+S(Panel Size)=33.8 ea/mm².

It should be noted that the spherical desiccant having such a dispersing density in the range of 10 ea/mm² to 250 ea/mm² can be manufactured steadily by adjusting the process of the dry dispersing apparatus during the practical manufacture. Therefore, all the spherical desiccant having the diameter in the range of 0.04 mm to 0 07 mm may be manufactured steadily by using the existing dry dispersing apparatus, thereby cost of production is decreased.

Further, as shown in FIG. 2, the OLED device may also comprise a spacer 27 provided between the array substrate 21 and the package substrate 22 for ensuring a thickness of the space between the array substrate and the package substrate.

In order to effectively support the array substrate 21 and the package substrate 22, the spacer 27 may be disposed on edges of the two substrates. In the embodiment of the present invention, the spacer 27 may be disposed inside of the frame sealant 24.

In an exemplary embodiment, the spacer 27 may include a spherical spacer of silicon. The diameter D of the spherical spacer of silicon is larger than the total thickness of all the layers between the array substrate 21 and the package substrate 22.

In the practical manufacture, the spherical spacer of silicon may be doped into the frame sealant 24, and the frame sealant 24 doped with the spherical spacer of silicon is coated at the edges of the array substrate 21 and the package substrate 22 to bond the two substrates together. The diameter D of the spherical spacer of silicon is larger than the total thickness of all the layers between the array substrate 21 and the package substrate 22. The total thickness of these layers between the array substrate 21 and the package substrate 22 is equal to the sum of the diameter d of the spherical desiccant 261, the thickness of the FTF on the array substrate 21, the thickness of the OLED structure 23 and the thickness of the moisture barrier layer 25. In this way, when the OLED device is subjected to an external force, it is possible to prevent deformation of the OLED device which may be caused by the interior height difference; thereby the quality of the display device is improved.

Further, in the embodiment of the present invention, the moisture barrier layer 25 may comprise a thin film of silicon nitride or silicon oxide. The thickness of the moisture barrier layer 25 may be in the range of 2000 Å to 20000 Å.

For example, a thin film of silicon nitride with a thickness of 10000 Å may be deposited on the surface of the OLED structure as the moisture bather layer 25. The thin film of silicon nitride with such a thickness may be manufactured by an existing technology such as low-temperature chemical vapor deposition. Further, the thin film of silicon nitride may effectively block the moisture and oxygen from entering the OLED structure 23, which further extends the life of the OLED structure. In addition, the thin film of silicon nitride may form a barrier layer between the OLED structure 23 and the spherical desiccant 261 to prevent the spherical desiccant 261 from directly contacting with the OLED structure 23, thus avoiding the damage to the OLED structure 23.

It should be noted that in the embodiment of the present invention, the desiccant particles particularly include at least one of calcium oxide and strontium oxide.

In the OLED device with such a structure, the same drying effect as that of the desiccant sheet may be obtained by the desiccant particles (for example, dispersed uniformly on the surface of the OLED structure), thus, the desiccant particles may replace the desiccant sheet in prior art, such that it is not necessary to dispose in the package substrate a recess for bonding the desiccant sheet, thus the cost of production and the thickness of the package substrate are decreased.

According to another embodiment of the present invention, there is provided a display device using the OLED device described above. The display device may comprise mobile phones, navigation systems, tablet computers, notebook computers, monitors or the like.

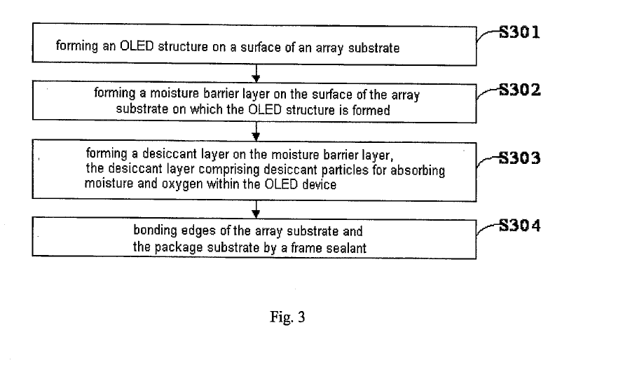

In an exemplary embodiment of the present invention, the display device comprises an OLED device including a package substrate and an array substrate, and a surface of the array substrate is formed with an OLED structure thereon, wherein edges of the array substrate and the package substrate are bonded by a frame sealant, and the OLED structure is positioned between the array substrate and the package substrate, further, a desiccant layer is disposed between the OLED structure and the package substrate, and the desiccant layer includes desiccant particles for absorbing the moisture and oxygen within the OLED device. In the display device with such a structure, the same drying effect as that of the desiccant sheet may be obtained by the desiccant particles (for example, dispersed uniformly on the surface of the OLED structure), thus, the desiccant particles may replace the desiccant sheet in prior art, such that it is not necessary to dispose in the package substrate a recess for bonding the desiccant sheet, thus the cost of production and the thickness of the package substrate are decreased. According to a further exemplary embodiment of the present invention, there is provided a method for packaging an OLED device, and as shown in FIG. 3, the method comprising the following steps:

Step S301: providing a package substrate and an array substrate, and forming an OLED structure on a surface of the array substrate.

Specifically, the OLED structure may be formed on the surface of the array substrate by various methods, and it is not intended to limit the present invention. For example, the OLED structure may be formed on the surface of the array substrate by a vapor deposition process.

Step S302: forming a moisture barrier layer on the surface of the array substrate on which the OLED structure is formed.

Step 303: forming a desiccant layer on the moisture barrier layer, the desiccant layer including desiccant particles for absorbing the moisture and oxygen within the OLED device.

It should be noted that it is not necessary to form the moisture barrier layer on the surface of the array substrate on which the OLED structure is formed. In this case, the desiccant layer may be formed at a surface of the package substrate facing the array substrate.

In an exemplary embodiment, the desiccant layer may be formed by spraying the desiccant particles for absorbing the moisture and oxygen within the OLED device onto the moisture barrier layer through the dry dispersing process, wherein the dry dispersion process is performed in a pure nitrogen atmosphere and concentration values of the water and oxygen are less than or equal to 10 ppm.

Step 304: bonding edges of the array substrate and the package substrate by a frame sealant.

In the method for packaging an OLED device according to the embodiment of the present invention, the OLED device comprises a package substrate and an array substrate a surface of which is formed thereon with an OLED structure, wherein edges of the array substrate and the package substrate are bonded by the frame sealant, and the OLED structure is positioned between the array substrate and the package substrate, further, a desiccant layer is disposed between the OLED structure and the package substrate, and the desiccant layer includes desiccant particles for absorbing the moisture and oxygen within the OLED device, and a moisture barrier layer for block moisture and oxygen is disposed on a surface of the OLED structure.

In the OLED device with such a structure, the packaging method and the display device according to the present invention, the same drying effect as that of the desiccant sheet may be obtained by the desiccant particles (for example, dispersed uniformly on the surface of the OLED structure), thus, the desiccant particles may replace the desiccant sheet in prior art, such that it is not necessary to dispose in the package substrate a recess for bonding the desiccant sheet, thus the cost of production and the thickness of the package substrate are decreased.

Further, the desiccant particles may be spherical desiccant, a diameter of which may be in the range of 0.04 mm to 0.07 mm. The spherical desiccant may be dispersed uniformly on the desiccant layer when a dry dispersing process is used. Moreover, the spherical desiccant has a large surface area, which may further facilitate absorbing the moisture and oxygen within the OLED device.

It should be noted that all the spherical desiccant having such a dispersing density in the range of 10 ea/mm² to 250 ea/mm² can be manufactured steadily by adjusting the process of the dry dispersing apparatus during the practical manufacture. Therefore, all the spherical desiccant having the diameter in the range of 0.04 mm to 0.07 mm may be manufactured steadily by using the existing dry dispersing apparatus, thereby cost of production is decreased.

Further, the method for packaging an OLED device further comprises a step of forming a spacer between the array substrate and the package substrate for ensuring a thickness of the space between the array substrate and the package substrate.

In order to effectively support the array substrate and the package substrate, the spacer may be disposed at edges of the two substrates. In the embodiment of the present invention, the spacer may be disposed inside of the frame sealant.

In an exemplary embodiment, the spacer may include a spherical spacer of silicon. The diameter of the spherical spacer of silicon is larger than the total thickness of all the layers between the array substrate and the package substrate.

In the practical manufacture, the spherical spacer of silicon may be doped into the frame sealant, and the frame sealant 24 doped with the spherical spacer of silicon is coated at the edges of the array substrate 21 and the package substrate 22 to bond the two substrates together. The diameter of the spherical spacer of silicon is larger than the total thickness of all the layers between the array substrate and the package substrate. The total thickness of these layers between the array substrate and the package substrate is equal to the sum of the diameter of the spherical desiccant, the thickness of the FTF on the array substrate, the thickness of the OLED structure and the thickness of the moisture barrier layer. In this way, when the OLED device is subjected to an external force, it is possible to prevent deformation of the OLED device which may be caused by the interior height difference; thereby the quality of the display device is improved.

Further, in the embodiment of the present invention, the moisture barrier layer may comprise a thin film of silicon nitride or silicon oxide. The thickness of the moisture barrier layer may be in the range of 2000 Å to 20000 Å.

For example, a thin film of silicon nitride with a thickness of 10000 Å may be deposited on the surface of the OLED structure as the moisture barrier layer 25. The thin film of silicon nitride with such a thickness may be manufactured by an existing technology such as low-temperature chemical vapor deposition. Further, the thin film of silicon nitride may effectively block the moisture and oxygen from entering the OLED structure 23, which further extends the life of the OLED structure. In addition, the thin film of silicon nitride may form a barrier layer between the OLED structure 23 and the spherical desiccant 261 to prevent the spherical desiccant 261 from directly contacting with the OLED structure 23, thus avoiding the damage to the OLED structure 23.

It should be noted that in the embodiment of the present invention, the desiccant particles particularly include at least one of calcium oxide and strontium oxide.

With such a method for packaging an OLED device, the same drying effect as that of the desiccant sheet may be obtained by the desiccant particles (for example, dispersed uniformly on the surface of the OLED structure), thus, the desiccant particles may replace the desiccant sheet in prior art, such that it is not necessary to dispose in the package substrate a recess for bonding the desiccant sheet, thus the cost of production and the thickness of the package substrate are decreased.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

What is claimed is:

1. An organic light-emitting diode (OLED) device comprising:
a package substrate; and
an array substrate a surface of which is formed with an OLED structure thereon,
wherein edges of the array substrate and the package substrate are bonded by a frame sealant, and the OLED structure is positioned between the array substrate and the package substrate;
wherein the OLED device further comprising:
a desiccant layer disposed between the OLED structure and the package substrate, the desiccant layer including desiccant particles for absorbing moisture and oxygen within the OLED device.

2. The OLED device as claimed in claim 1, wherein the desiccant layer is disposed on a surface of the package substrate facing the array substrate.

3. The OLED device as claimed in claim 1, wherein a surface of the OLED structure is provided thereon with a moisture barrier layer for blocking the moisture and oxygen; and
the desiccant layer is positioned between the moisture barrier layer and the package substrate.

4. The OLED device as claimed in claim 3, wherein the desiccant layer is disposed on the moisture barrier layer.

5. The OLED device as claimed in claim 3, wherein the desiccant layer is disposed on a surface of the package substrate facing the array substrate.

6. The OLED device as claimed in claim 1, wherein the desiccant particles include at least one of calcium oxide and strontium oxide.

7. The OLED device as claimed in claim 1, the desiccant particles comprise spherical desiccant, a diameter of the spherical desiccant being in the range of 0.04 mm to 0.07 mm.

8. The OLED device as claimed in claim 1, wherein the OLED device further comprises a spacer provided between the array substrate and the package substrate for ensuring a thickness of the space between the array substrate and the package substrate.

9. The OLED device as claimed in claim 8, wherein the spacer is positioned within the frame sealant.

10. The OLED device as claimed in claim 8, wherein the spacer comprises a spherical spacer of silicon, and
a diameter of the spherical spacer of silicon is larger than a total thickness of all the layers between the array substrate and the package substrate.

11. The OLED device as claimed in claim 3, wherein the moisture barrier layer comprises a thin film of silicon nitride or silicon oxide; and
a thickness of the moisture barrier layer is in the range of 2000 Å to 20000 Å.

12. A display device comprising the OLED as claimed in claim 1.

13. A method for packaging an OLED device comprising:
providing a package substrate and an array substrate;
forming an OLED structure on a surface of the array substrate;
forming a desiccant layer between the OLED structure and a surface of the package substrate facing the array substrate, the desiccant layer including desiccant particles for absorbing moisture and oxygen within the OLED device; and
bonding edges of the array substrate and the package substrate by a frame sealant.

14. The method for packaging an OLED device as claimed in claim 13, wherein the desiccant layer is formed on the surface of the package substrate facing the array substrate.

15. The method for packaging an OLED device as claimed in claim 14, wherein the desiccant layer is formed by spraying, through a dry dispersion process, the desiccant particles for absorbing the moisture and oxygen within the OLED device onto the surface of the package substrate facing the array substrate, wherein the dry dispersion process is performed in a pure nitrogen atmosphere and concentration values of the water and oxygen are less than or equal to 10 ppm.

16. The method for packaging an OLED device as claimed in claim 13, further comprising:
forming a moisture barrier layer on the surface of the array substrate on which the OLED structure is formed,
wherein the step of forming a desiccant layer comprises forming the desiccant layer on the moisture barrier layer.

17. The method for packaging an OLED device as claimed in claim 16, wherein the step of forming the desiccant layer on the moisture barrier layer comprises:
forming the desiccant layer by spraying, through a dry dispersion process, the desiccant particles for absorbing the moisture and oxygen within the OLED device onto the moisture barrier layer, wherein the dry dispersion process is performed in a pure nitrogen atmosphere and concentration values of the water and oxygen are less than or equal to 10 ppm.

18. The method for packaging an OLED device as claimed in claim 13, wherein the step of forming an OLED structure on a surface of the array substrate comprises:
forming the OLED structure on the surface of the array substrate by a vapor deposition process.

19. The method for packaging an OLED device as claimed in claim 13, wherein the desiccant particles are spherical desiccant, a diameter of the spherical desiccant being in the range of 0.04 mm to 0.07 mm.

20. The method for packaging an OLED device as claimed in claim 13, further comprising:
providing a spacer between the array substrate and the package substrate for ensuring a thickness of the space between the array substrate and the package substrate.
